(19) United States
(12) Patent Application Publication
(10) Pub. No.: US 2011/0049529 A1
(43) Pub. Date: Mar. 3, 2011

(54) GaN-BASED SEMICONDUCTOR ELEMENT AND METHOD OF MANUFACTURING THE SAME

(75) Inventors: Yoshihiro Sato, Tokyo (JP); Takehiko Nomura, Tokyo (JP); Hiroshi Kambayashi, Tokyo (JP); Shinji Nagata, Tokyo (JP)

(73) Assignee: FURUKAWA ELECTRIC CO., LTD., Tokyo (JP)

(21) Appl. No.: 12/943,448

(22) Filed: Nov. 10, 2010

(30) Foreign Application Priority Data
May 22, 2009 (JP) 2009-124068

(51) Int. Cl. H01L 29/20; H01L 21/28

(52) U.S. Cl. 257/76; 438/585; 257/E29.089; 257/E21.209

(57) ABSTRACT

Provided is a GaN series semiconductor element, which is capable of obtaining an adequate normally-off characteristic, and a manufacturing method thereof.

In a GaN series semiconductor element that comprises an operating layer comprising a GaN series compound semiconductor, a gate insulating film that is formed on the operating layer, and a gate electrode that is formed on the gate insulating film, the gate insulating is a SiO₂ film of which an infrared absorption peak that corresponds to the vibration energy of a Si—H bond does not appear in the absorption spectrum of transmitted light that is obtained by the Fourier transform infrared spectroscopy method. This kind of SiO₂ film is a high-quality SiO₂ film in which the occurrence of Si—H bonds and dangling bonds is suppressed. With this kind of construction, adverse effects on the control of the threshold value of the GaN series semiconductor element are also suppressed, so an adequate normally-off characteristic is obtained.

### BACKGROUND OF THE INVENTION

1. Field of the Invention

The present invention relates to a GaN-series semiconductor element comprising a nitride-series compound semiconductor that is used as a power-electronics device or high-frequency amplification device, and to the manufacturing method thereof.

2. Description of the Related Art

Wide bandgap semiconductors that are representative of group III-V nitride-series compound semiconductors have a high breakdown voltage, good electron transport properties, and good thermal conductivity, so are extremely promising as materials for semiconductor devices that are used in high-temperature environments, require high power or require high frequency. For example, in an AlGaN/GaN heterostructure, 2-dimensional electron gas is produced at a boundary face due to the piezoelectric effect. This 2-dimensional electron gas has high electron mobility and high carrier density, and has already been put into practical use in high-frequency devices. Moreover, heterojunction field-effect transistors (HFET) that are used in an AlGaN/GaN heterostructure have low ON resistance and high switching speed, making them capable of high-temperature operation. These characteristics are very suitable for applications as high-power switching elements.

A typical AlGaN/GaN HFET is a normally-on device in which drain current flows when a bias is not applied to the gate, and drain current is blocked by applying a negative voltage to the gate. On the other hand, in a high-power switching element, in order to maintain safety when a device fails (fail safe), a normally-off device is preferred in which current does not flow when a bias (positive voltage) is not applied to the gate, and current flows by applying a positive voltage to the gate.

In order to realize a normally-off device, it is necessary to employ MOS structure, and research in this area is currently being advanced by several research organizations (for example, refer to non-patent document 1).

In addition, patent document 1 discloses a MOS field-effect transistor (MOSFET) in which an AlGaN electron-supply layer is etched to the channel layer in the gate portion, and an insulating layer is formed on the etching surface of the channel layer. In this structure, an AlGaN/GaN heterojunction structure is formed between the gate and drain, and the 2-dimensional electron gas that is generated due to this heterojunction structure has high electron mobility, so it is possible to prevent an increase in ON resistance even when there is low sheet carrier density necessary for maintaining a high breakdown voltage. In other words, this is suitable structure for realizing both high breakdown voltage and low ON resistance.

Normally, in a Si series MOS field-effect transistor (MOSFET), a SiO₂ gate insulating film (gate oxidation film) is formed due to the thermal oxidation of Si.

However, in conventional technology for making a GaN series MOSFET, a SiO₂ film that is formed by plasma CVD (Chemical Vapor Deposition) is used as the gate insulating film.

However, in a conventional GaN series MOSFET that uses a SiO₂ film that is formed by plasma CVD as the gate insulating film, it is difficult to control the threshold voltage, so an adequate normally-off characteristic could not be obtained.

This will be explained in detail.

FIGS. 11A and 11B show the gate voltage (g) and drain current (Id) characteristics (Vg-Id characteristics) of the same conventional GaN series MOSFET. In the graph of FIG. 11A, the vertical axis that represents the drain current Id is a linear axis, and in the graph of FIG. 11B the vertical axis that represents Id is a logarithmic axis.

In the graph of FIG. 11A, the lowest point (gate voltage where Id=0) of the straight line 101 that extrapolates the curve 100 that shows the Vg-Id characteristic exceeds 0 V, so the conventional GaN series MOSFET shown in this graph at a first glance appears to obtain a normally-off characteristic.

However, in the curve 102 of FIG. 11B that shows the Vg-Id characteristic with the vertical axis being a logarithmic axis, when Vg=0 V, a large leakage current on the order of about 1×10⁻⁶ (A) flows. The leakage current (Id) that can practically be allowed for a normally-off GaN series MOSFET is 1×10⁻¹² (A) or less, so when Vg=0 V, a large leakage current of nearly 1×10⁻⁶ (A), which is 10⁶ times the allowed value, flows. In other words, a conventional GaN series MOSFET having the Vg-Id characteristics shown in FIG. 11B does not obtain an adequate normally-off characteristic.

### [Patent Document 1]

International Publication No. WO 03/071607

### [Non-patent Document 1]

Huang W, Khan T, Chow T P: Enhancement-Mode n-Channel GaN MOSFETs on p and n⁻ GaN/Sapphire substrates. In: 18th International Symposium on Power Semiconductor Devices and ICs (ISPSD) 2006 (Italy), 10-1.

In a GaN series MOSFET, methods of changing the amount of Mg (p-type dopant) that is doped on the GaN layer that is used as a channel, and changing the type (work factor) of gate electrode are known as methods for shifting the threshold voltage, however, the theoretical threshold value can not be obtained.

Therefore, the inventors considered whether the characteristics of the gate insulating film (SiO₂ film) that is formed by the plasma CVD method were the reason that the threshold value of a GaN series semiconductor element such as a GaN series MOSFET could not be changed to the theoretical value, and performed various studies of gate insulating film (SiO₂ film).

### SUMMARY OF THE INVENTION

It is an object of the present invention to at least partially solve the problems in the conventional technology.

The inventors found that in a GaN series semiconductor element such as a GaN series MOSFET, dangling bonds in a SiO₂ film that is formed by the plasma CVD method as a gate insulting film are a cause of not being able to change the threshold value of the GaN series semiconductor element according to theory. In other words, SiO₂ film comprises four Si—O bonds in which Si atoms are bonded with oxygen (O) atoms in a main bond chain (bond). However, it was found that in SiO₂ film that is formed by the plasma CVD method, part of the Si—O bonds are broken and dangling bonds in which the Si atoms are not terminated occur, the crystal structure of the SiO₂ film becomes disturbed such as Si—H bonds occurring in which H (hydrogen) terminates the Si, and in this portion positive or negative charge occurs, having an adverse effect on the threshold value of the GaN series semiconductor element.

The present invention is based on the finding described above.

A first form of the present invention is a GaN series semiconductor element that comprises: an operating layer comprising a GaN series compound semiconductor; a gate insulating film that is formed on the operating layer; and a gate electrode that is formed on the gate insulating layer; wherein the gate insulating film is a SiO₂ film of which an infrared absorption peak that corresponds to the vibration energy of a Si—H bond does not appear in the absorption spectrum of transmitted light that is obtained by the Fourier transform infrared spectroscopy method.

A second form of the present invention is a manufacturing method for manufacturing a GaN series semiconductor element that comprises an operating layer comprising a GaN series compound semiconductor layer that is stacked on a substrate via a buffer layer, a gate film insulating film that is formed on the operating layer, and a gate electrode that is formed on the gate insulating film, wherein the process of forming the gate insulating film includes a process of forming an SiO₂ film by the atmospheric pressure CVD method.

The above and other objects, features, advantages and technical and industrial significance of this invention will be better understood by reading the following detailed description of presently preferred embodiments of the invention, when considered with the accompanying drawings.

### BRIEF DESCRIPTION OF THE DRAWINGS

FIG. 1 is a cross-sectional drawing showing the construction of a GaN series semiconductor element of an embodiment of the present invention.

FIG. 2 is a drawing explaining the method of manufacturing the GaN series semiconductor element shown in FIG. 1.

FIG. 3 is a drawing explaining the method of manufacturing the GaN series semiconductor element shown in FIG. 1.

FIG. 4 is a drawing explaining the method of manufacturing the GaN series semiconductor element shown in FIG. 1.

FIG. 5 is a drawing explaining the method of manufacturing the GaN series semiconductor element shown in FIG. 1.

FIG. 6 is a drawing explaining the method of manufacturing the GaN series semiconductor element shown in FIG. 1.

FIG. 7 is a drawing explaining the method of manufacturing the GaN series semiconductor element shown in FIG. 1.

FIG. 8 is a graph showing the Vg-Id characteristics of the GaN series semiconductor element shown in FIG. 1

FIG. 9A is a graph showing the infrared absorption spectrum of the SiO₂ film that is formed by the APCVD method, and FIG. 9B is a graph showing the waveform obtained by taking the derivative of the infrared absorption spectrum shown in FIG. 9A.

FIG. 10A is a graph showing the infrared absorption spectrum of the SiO₂ film that is formed by the P-CVD method, and FIG. 10B is a graph showing the waveform obtained by differentiating the infrared absorption spectrum shown in FIG. 10A.

FIGS. 11A and 11B are graphs showing the Vg-Id characteristics of the same conventional GaN series MOSFET.

### DETAILED DESCRIPTION OF THE PREFERRED EMBODIMENTS

The preferred embodiment of the present invention will be explained in detail with reference to the drawings. In the explanation of the embodiments, the same reference numbers will be used for identical parts, and any redundant explanation will be omitted.

### First Embodiment

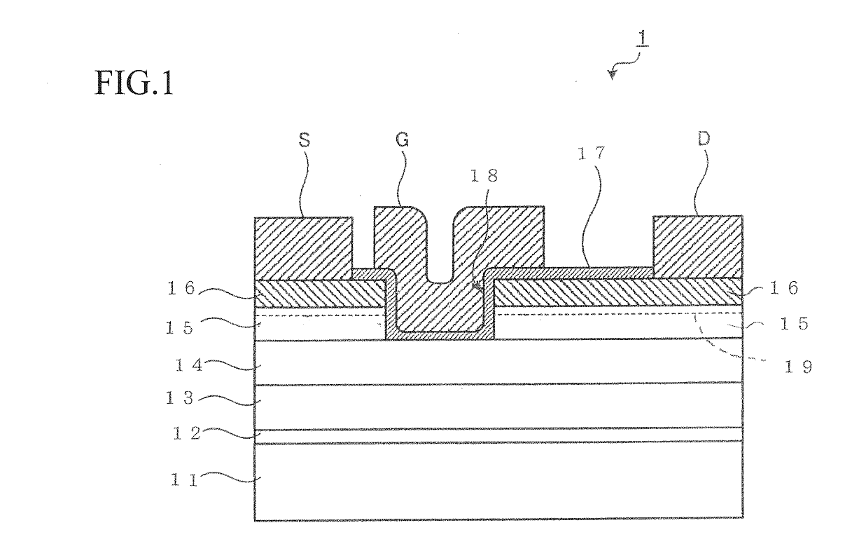

FIG. 1 is a cross-sectional drawing of the construction of a GaN series semiconductor element 1 of a first embodiment of the present invention.

The GaN series semiconductor element 1 is a MOSFET. The GaN series semiconductor element 1 comprises an AlN layer 12, a buffer layer 13 that is formed having alternately stacked GaN layers and AlN layers, and a channel layer 14 comprising a p-GaN layer, all formed on a substrate 11 made from a material such as sapphire, SiC or Si.

An electron transit layer 15 comprising undoped GaN (un-GaN), and an electron supply layer 16 comprising a GaN series semiconductor (AlGaN) having larger bandgap energy than the electron transit layer 15 are sequentially stacked on the channel layer 14, to form an operating layer. The electron transit layer 15 and part of the electron supply layer 16 (gate electrode formation region) are removed to a depth that reaches the channel layer, to form a recess section 18.

A source electrode 21 and drain electrode 22 are formed on the electron supply layer 16 on both sides of the recess section 18. A SiO₂ gate insulating film 17 is formed on the electron supply layer 16 and on the inner surface of the recess section 18, and a gate electrode 23 is further formed on the gate insulating film 7 in the recess section 18. The gate insulating film 17 is a SiO₂ film that is formed by the atmospheric pressure CVD (hereafter, referred to as “APCVD”) method.

In this way, in the GaN series semiconductor element 1, the electron supply layer 16 comprises a channel layer directly underneath the gate insulating film 17, and first and second electron supply layers that are separated from each other on both side of a gate section having MOS construction are formed from the gate insulating film 17 and gate electrode 23. The electron transit layer 15 is formed between the channel layer 14 and first electron supply layer (the electron supply layer further on the left side than the recess section in FIG. 1), and between the channel layer 14 and the second electron supply layer (the electron supply layer further on the right side than the recess section in FIG. 1). The electron transit layer 15 is formed of a p-type or undoped GaN series compound semiconductor having a lower impurity concentration than the channel layer 14.

In this GaN series semiconductor element 1, the electron supply layer 16 forms a heterojunction with the surface of the electron transit layer 15, so a 2-dimensional electron gas layer 19 is formed near the boundary face. Therefore, this 2-dimensional electron gas layer 19 becomes a carrier, and thus the electron transit layer 15 has low resistance and high mobility and the ON resistance of the GaN series semiconductor element 1 can be decreased.

Moreover, in this GaN series semiconductor element 1, there is no electron supply layer 16 in the area directly underneath the gate electrode of the channel layer 14, so the 2-dimensional electron gas layer 19 is not formed. When a positive voltage is applied to the gate electrode 23 that is equal to or greater than the threshold value, an inversion layer is formed on the channel layer 14 that is directly underneath the gate electrode 23. This inversion layer is continuous with the 2-dimensional electron gas layer 19 that is formed on the right and left of the gate section of the MOS structure to form a channel through which drain current flows.

In this way, operation of a normally-off field effect transistor is obtained.

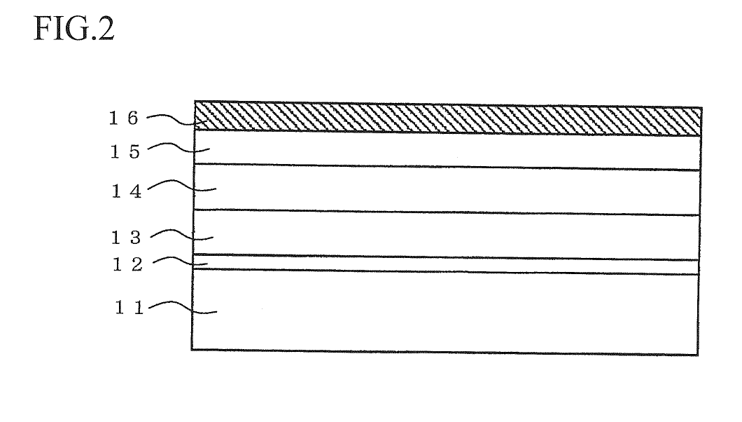

Next, the method for manufacturing the GaN series semiconductor element shown in FIG. 1 will be explained. FIG. 2 to FIG. 7 are drawings explaining an example of the manufacturing method of a GaN series semiconductor element 1.

First, as shown in FIG. 2, a Si substrate 11, having plane <111> as the main surface, is set in a MOCVD apparatus, and using Hydrogen gas having a concentration of 100% as the carrier gas, tri-methyl gallium (TMGa), tri-methyl aluminum (TMAl) and ammonia (NH₃) are injected, and at a growth temperature of 1050° C., an AlN layer, a buffer 13 layer that is formed by alternately stacking GaN layers and AlN layers, and a channel layer 14 made from p-GaN are sequentially and epitaxially grown on the substrate 11. Using bis cyclopentadienyl magnesium (Cp₂Mg) as a p-type doping source for the channel layer 14, the Cp₂Mg flow rate is adjusted so that the Mg concentration becomes approximately 1×10¹⁷ cm⁻³. Measurement of this Mg concentration is performed using a secondary ion-microprobe mass spectrometer (SIMS).

Next, both TMGa and NH₃ are injected, and at a growth temperature of 1050° C., an electron transit layer 15 made from undoped GaN is epitaxially grown on the channel layer 14. After that, TMAl, TMGa and NH₃ are each injected to epitaxially grow an electron supply layer 16 comprising AlGaN having an Al composition of about 25%.

In the description above, the buffer layer 13 comprises eight staked GaN/AlN composite layers each having a thickness of 200 nm/200 nm. The thicknesses of the AlN layer 12, channel layer 14, electron transit layer 15 and electron supply layer 16 are 100 nm, 500 nm, 100 nm and 20 nm, respectively.

Next, using the plasma CVD (PCVD) method, a 500 nm thick mask layer made of amorphous silicon (a-Si) or SiO₂ film is formed on the electron supply layer 16, then patterning is performed using photolithography and CF₄ gas to form an opening section (not shown in the figure) in the location that corresponds to the gate electrode formation area.

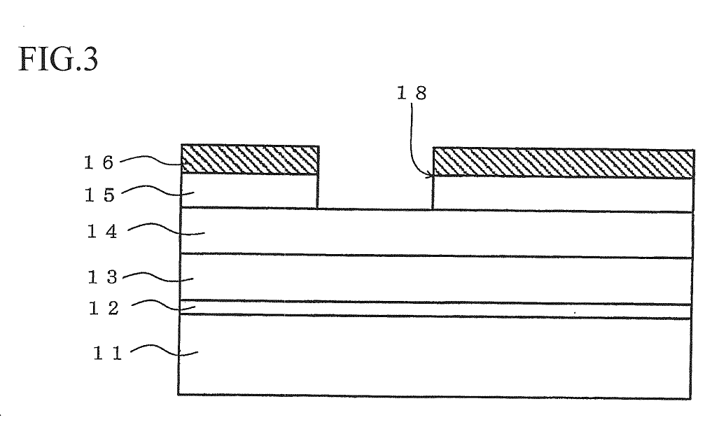

Next, as shown in FIG. 3, with the aforementioned mask layer (not shown in the figure) as a mask and using Cl₂ gas, part of the electron transit layer 15 and electron supply layer 16 is removed by etching to form a recess section 18 so that the surface of the channel layer 14 is exposed.

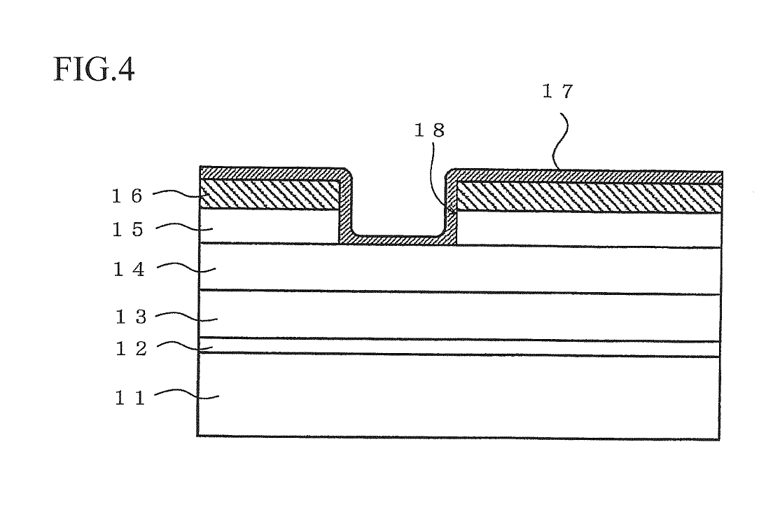

The mask layer (not shown in the figure) is then removed. After that, as shown in FIG. 4, a 60 nm thick SiO₂ gate insulating film 17 is formed on the inner surface of the recess section 18 that includes the surface of the channel layer 14.

This gate insulating film 17 is formed by the atmospheric pressure CVD (APCVD) method as a film on the surface of the electron supply layer 16 and inner surface of the recess section 18 that includes the surface of the channel layer 14.

When doing this, the film formation temperature is 400° C., and the pressure is atmospheric pressure (450 to 1100 hPa). In addition, silane and oxygen are used as raw materials, and nitrogen is used as the dilution gas. The flow rates of these gases are adequately regulated so that they match the conditions of each device.

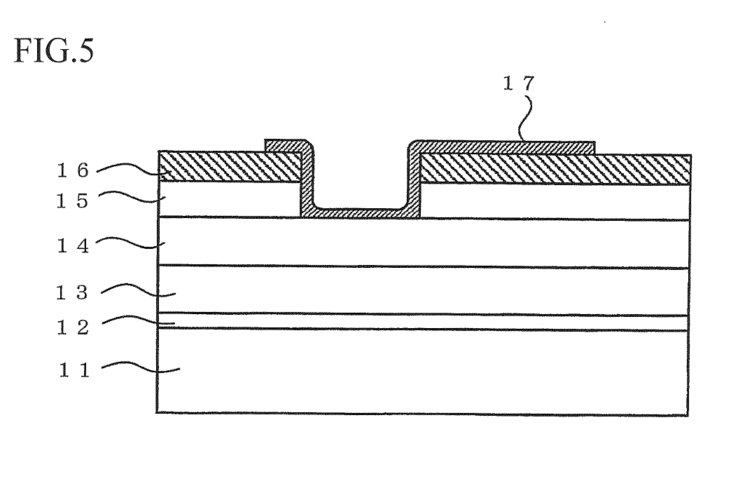

Next, after masking all the areas except where the source electrode 21 and drain electrode 22 are to be formed, the gate insulating film 17 is removed using hydrofluoric acid as shown in FIG. 5.

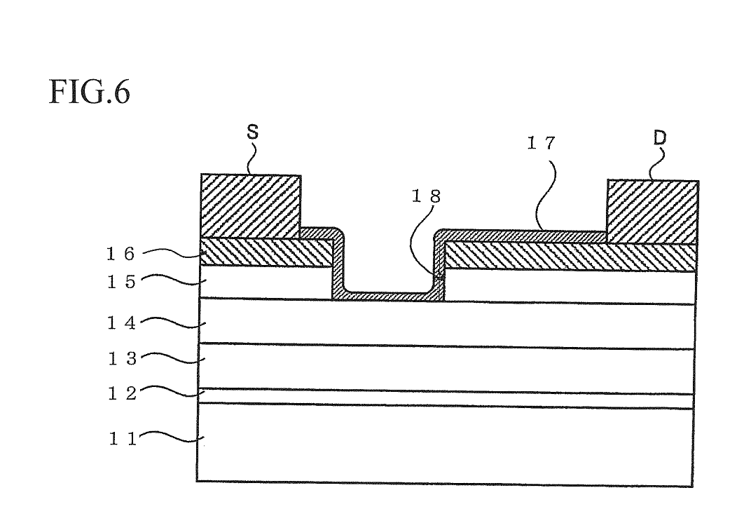

After that, as shown in FIG. 6, the liftoff method is used to form the source electrode 21 and drain electrode 22 in the area where the gate insulating film 17 was removed. The source electrode 21 and drain electrode 22 are formed in the order of a Ti layer and Al layer from the side of the surface of the electron supply layer 16.

The thickness of the Ti layer is, for example, 25 nm, and the thickness of the Al layer, for example, is 300 nm. The Ti layer and Al layer are formed by the sputtering method or vacuum deposition method. After that, annealing is performed at 600° C. for 10 minutes.

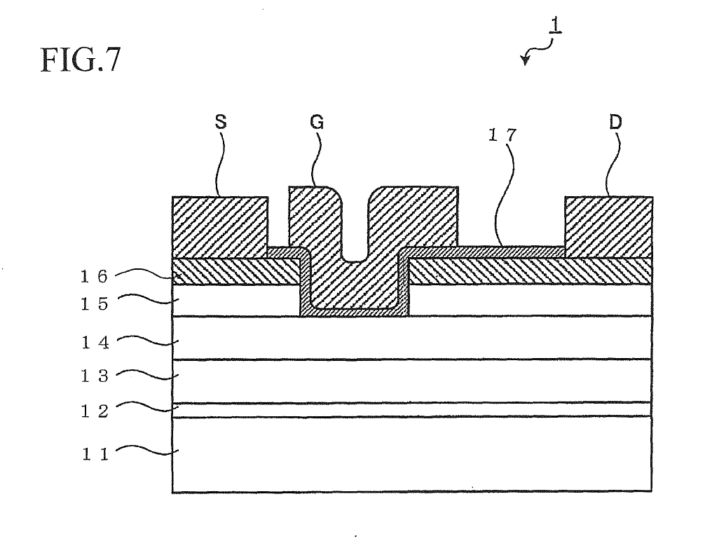

Next, as shown in FIG. 7, the liftoff method is used to form the gate electrode 23 on the gate insulating film 17. The gate electrode 23 is formed in the order of a Ti layer and Au layer from the side of the surface of the gate insulating film 17. Both the Ti layer and Au layer are formed by the sputtering method or vacuum deposition method.

From this, the GaN series semiconductor element 1 shown in FIG. 1 is completed.

The GaN series semiconductor element 1 of the first embodiment described above has the following advantages.

A SiO₂ film is formed as the gate insulating film 17 by the atmospheric CVD (APCVD) method and not the plasma CVD (P-CVD) method, so a high-quality SiO₂ film can be made. The GaN series semiconductor element 1 has this high-quality SiO₂ film as the gate insulating film 17, so an adequate normally-off characteristic is obtained.

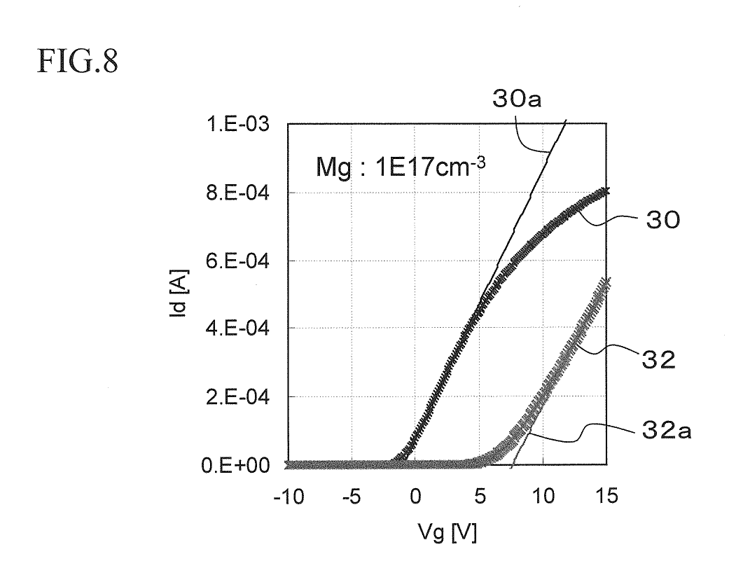

FIG. 8 shows the Vg-Id characteristics of the GaN series semiconductor element 1 of an example having a SiO₂ film formed by the APCVD method as the gate insulating film 17, and the Vg-Id characteristics of a GaN series semiconductor element of a comparative example having a SiO₂ film formed by the PCVD method as the gate insulating film 17.

### Explanation of the Examples and Comparison Examples

First, a MOSFET having the structure described below was made as an example of the invention.

A 100 nm thick AlN layer 12, an approximately 2 μm thick buffer layer 13, which was formed by alternately stacking 200 nm thick GaN layers and 20 nm thick AlN layers, and a 500 nm thick channel layer 14 made from a p-GaN layer are formed on a Si substrate, whose main surface is plane <111>.

A 100 nm electron transit layer 15 comprising undoped GaN (u-GaN) and a 20 nm thick electron supply layer 16 comprising AlGaN are sequentially stacked on the channel layer 14. Part of the electron transit layer 15 and electron supply layer 16 (gate electrode formation region) is removed to a depth that reaches the channel layer 14 to form a recess section 18.

A source electrode 21 and drain electrode 22 comprising Ti/Al are formed on the electron supply layer 16 on both sides of the recess section 18. A SiO₂ gate insulating film 17 is formed on the electron supply layer 16 and on the inner surface of the recess section 18 that has the surface of the channel layer 14 as the bottom surface; then a gate electrode 23 is formed on the gate insulating film 17 in the recess section 18. The gate insulating film 17 was formed by the APCVD method.

The formation conditions for the gate insulating film 17 by the APCVD method are a growth temperature of 400° C. and a growth pressure that is atmospheric pressure. Using silane and oxygen as the raw material gases. and nitrogen as the carrier gas, a 60 nm thick film was formed.

The MOSFET of a comparative example was the same as the GaN series semiconductor element 1 except that the SiO₂ film used as the gate insulating film 17 was formed by the PCVD method.

The gate insulating film 17 formed by the PCVD method was formed under the conditions of silane (SiH₄) and nitrous oxide (N₂O) as the raw material gas, a formation temperature of 300° C. and pressure of 177 Pa.

FIG. 8 is a graph that shows the results of measuring the drain current in both the example and comparative example when the Vds (voltage between the source and drain) was fixed at 0.1 V, and the gate voltage was changed from −10 V to 15 V.

The curve 32 in FIG. 8 is the Vg-Id characteristic of the MOSFET of an example of the present invention that was made under the conditions described above, and the straight line 32a is an approximate linearization of the curve 32 when the gate voltage is 10 V to 15 V. Curve 30 in FIG. 8 is the Vg-Id characteristic of the MOSFET of a comparative example, and the straight line 30a is a linear approximation of the curve 30 when the gate voltage is 0 V to 5 V. The MOSFETs of the example and comparative example only differ in the method used for forming the SiO₂ film that is used as the gate insulating film 17, the other construction is the same.

As can be seen in FIG. 8, in the MOSFET of the example, the minimum point on the straight line 32a (gate voltage Vg when Id=0) becomes about 7 V, and since it exceeds 0 V, an adequate normally-off characteristic is obtained. On the other hand, in the GaN series semiconductor element of the comparative example, the minimum point of the straight line 30a does not exceed 0 V, so it can be seen that an adequate normally-off characteristic is not obtained.

### <Infrared Absorption Spectrum Measurement of SiO₂ Film>

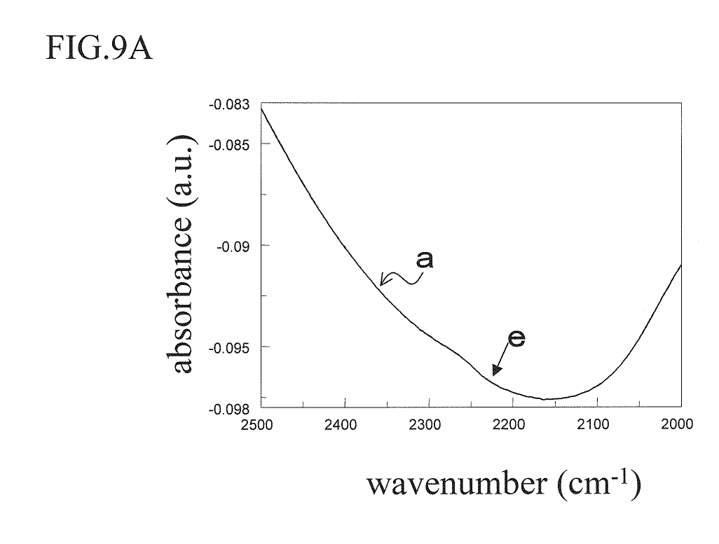

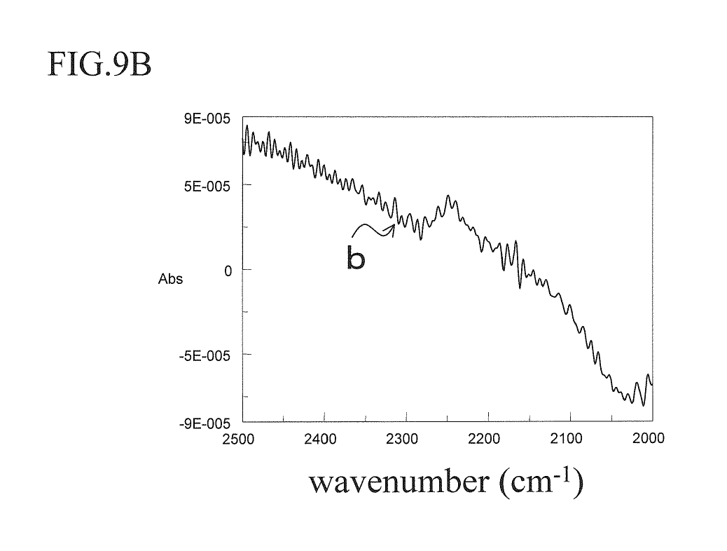

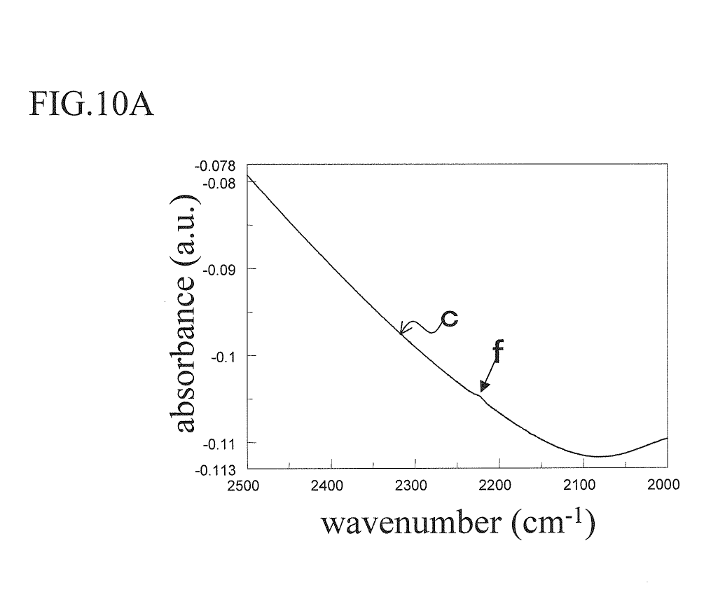

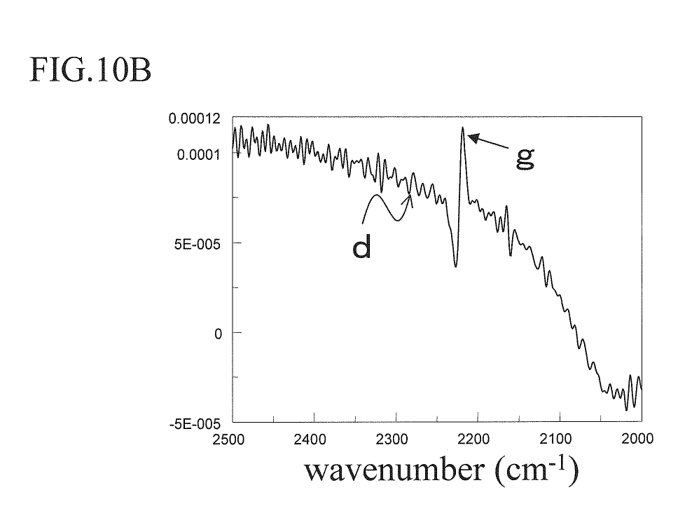

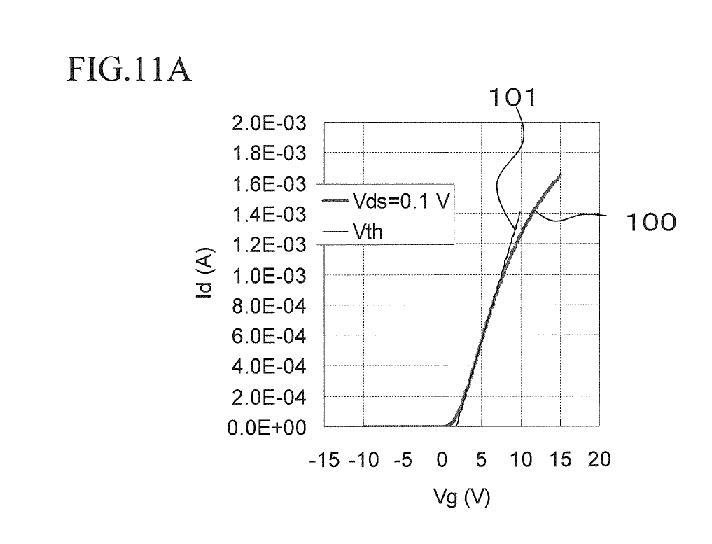

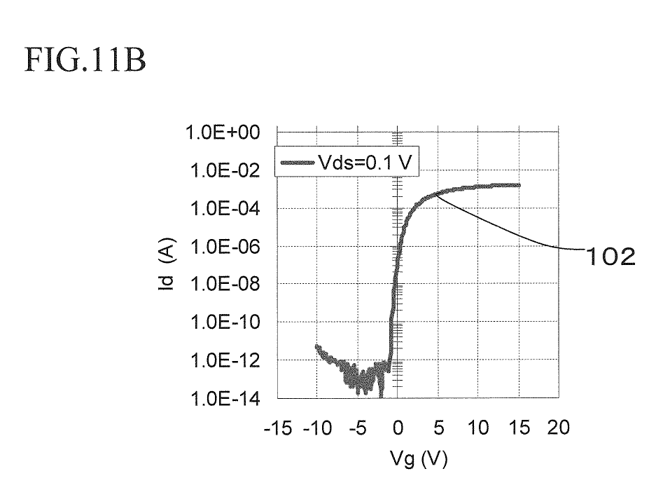

Next, the characteristics of the SiO₂ film formed by the APCVD method and the SiO₂ film formed by the PCVD method will be explained based on FIG. 9 and FIG. 10.

A sample 1 was created by forming a 1 μm thick SiO₂ film on a 500 μm thick Si substrate by the APCVD method. In FIG. 9A, the curve ‘a’ shows the spectrum near 2200 [cm⁻¹] of the infrared absorption spectrum when the sample 1 was irradiated by infrared light from the side of the Si substrate and the light that was transmitted was measured by the Fourier transform infrared spectroscopy (FTIR) method. The spectrum shown in FIG. 9A is based on the spectrum that is obtained by measuring the light that is transmitted only through the Si substrate. The waveform ‘b’ of FIG. 9B is the waveform obtained by differentiating the infrared absorption spectrum shown by curve ‘a’.

Similarly, a sample 2 was made by forming a 1 μm thick SiO₂ film on a 500 μm thick Si substrate by the PCVD method. In FIG. 10A, the curve ‘c’ shows the spectrum near 2200 cm⁻¹ of the infrared absorption spectrum when the sample 2 was irradiated by infrared light from the side of the Si substrate and the light that was transmitted was measured by the Fourier transform infrared spectroscopy (FTIR) method. Also, the waveform ‘2’ of FIG. 10B is the waveform obtained by differentiating the infrared absorption spectrum shown by curve ‘c’.

The absorbance is represented by the vertical axis in FIG. 9 and FIG. 10, and when the intensity of infrared light before passing through the sample is taken to be A, and the intensity of the infrared light after passing through the sample is taken to be B, the absorbance can be represented by Equation (1) as given below.

Absorbance=log₁₀(A/B) Equation (1)

As is shown by the section ‘e’ in FIG. 9A and waveform ‘b’ in FIG. 9B, it can be seen that near the wavenumber 2240 [cm⁻¹] of the irradiated infrared light (within the wavenumber range of 2200 [cm⁻¹] to 2250 [cm⁻¹]) an infrared absorption peak that corresponds to the vibration energy of the Si—H bond does not appear in the infrared absorption spectrum of the SiO₂ film that was formed by the APCVD method. From this it can be seen that in the SiO₂ film that was formed by the APCVD method, generation of Si—H bonds was suppressed. That is, in the SiO₂ film that was formed by the APCVD method, generation of dangling bonds that are the cause of Si—H bonds is also suppressed, and in doing so, it is conjectured that generation of an electric charge inside the SiO₂ film is suppressed.

On the other hand, as shown in section ‘f’ of FIG. 10A and section ‘g’ of FIG. 10B, i t can be seen that near the wavenumber 2240 [cm⁻¹] an infrared absorption peak that corresponds to the vibration energy of the Si—H bond appears in the infrared absorption spectrum of the SiO₂ film that was formed by the PCVD method. From this it can be seen that in the SiO₂ film that was formed by the PCVD method, part of the Si—O bond is broken, and a Si—H bond is generated where H (hydrogen) terminates the Si, so it is conjectured that dangling bonds are generated in which there are no atoms terminating the Si. There are dangling bonds in a SiO₂ compound, and positive or negative electric charge is generated in that portion, so is considered to have an adverse effect on controlling the threshold value of the GaN series semiconductor element.

It can be seen from this that by forming a SiO₂ film by the APCVD method as the gate insulating film 17, a high-quality SiO₂ film is obtained, and it is possible to optimally control the threshold value. In addition, since there is this kind of high-quality SiO₂ film used as the gate insulating film 17, an adequate normally-off characteristic can be obtained in the GaN series semiconductor element 1.

In the embodiments described above, an example was given of using AlGaN/GaN as the combination of the electron supply layer and electron transit layer, however, instead of this, applying material combinations such as AlInGaN/GaN, GaN/InGaN, GaN/GaNAs, GaN/GaInNAsP, GaN/GaInNP, GaN/GaNP, AlGaNInNAsP/GaN or AlGaN/AlInGaN is also possible.

Although the invention has been described with respect to specific embodiments for a complete and clear disclosure, the appended claims are not to be thus limited, but are to be construed as embodying all modifications and alternative constructions that may occur to one skilled in the art that fairly fall within the basic teaching herein set forth.

What is claimed is:

1. A GaN series semiconductor element comprising:
an operating layer comprising a GaN series compound semiconductor;
a gate insulating film that is formed on said operating layer; and
a gate electrode that is formed on said gate insulating layer; wherein
said gate insulating film is a SiO₂ film of which an infrared absorption peak that corresponds to the vibration energy of a Si—H bond does not appear in the absorption spectrum of transmitted light that is obtained by the Fourier transform infrared spectroscopy method.

2. The GaN series semiconductor element of claim 1 wherein said absorption peak is within the wavenumber range 2200 [cm⁻¹] to 2250 [cm⁻¹].

3. The GaN series semiconductor element of claim 1 wherein
said operating layer comprises:
an electron transit layer comprising a GaN series compound semiconductor; and
an electron supply layer comprising a GaN series compound semiconductor having a larger bandgap energy than said electron transit layer.

4. The GaN series semiconductor element of claim 1 wherein
said operating layer comprises:
a channel layer comprising a p-type GaN series compound semiconductor;
an electron transit layer comprising a GaN series semiconductor that is formed on said channel layer; and
an electron supply layer comprising a GaN series semiconductor having a larger bandgap energy than said electron transit layer; wherein
said operating layer has a recess section that is formed from the surface of said electron supply layer to said channel layer in a portion where said gate electrode will be formed.

5. A manufacturing method for manufacturing a GaN series semiconductor element that comprises an operating layer comprising a GaN series compound semiconductor layer that is stacked on a substrate via a buffer layer, a gate film insulating film that is formed on said operating layer, and a gate electrode that is formed on said gate insulating film, wherein
the process of forming said gate insulating film includes a process of forming a SiO₂ film by the atmospheric pressure CVD method.
